(19) United States
(12) Patent Application Publication
(10) Pub. No.: US 2012/0242362 A1
(43) Pub. Date: Sep. 27, 2012

(54) TEST APPARATUS

(75) Inventors: ZHI-YONG ZHAO, Shenzhen City (CN); TAI-CHEN WANG, Tu-Cheng (TW); GUANG-FENG OU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/093,869

(22) Filed: Apr. 26, 2011

(30) Foreign Application Priority Data
Mar. 23, 2011 (CN) 201110070388.9

(51) Int. Cl. G01R 1/067

(52) U.S. Cl. 324/755.1

(57) ABSTRACT

A test apparatus includes a circuit board and an expansion slot. A number of golden fingers are arranged on a first side of the circuit board. A second side of the circuit board is connected to a bottom of the expansion slot. The golden fingers are electrically connected to the expansion slot. A number of first test pads and second test pads are arranged on the circuit board between the first side and the second side. The first and second test pads have different shapes, sizes, and/or colors. The first and second test pads are electrically connected to pins in the expansion slot.

### BACKGROUND

1. Technical Field

The present disclosure relates to a test apparatus.

2. Description of Related Art

When a motherboard is tested, users usually solder testing probes to a memory module which is plugged into the motherboard and the motherboard receive signals from the memory, this is a delicate task and often result in damage to the memory.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a schematic diagram of an exemplary embodiment of a test apparatus.

FIG. 2 is a schematic diagram of the test apparatus in a state of use.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

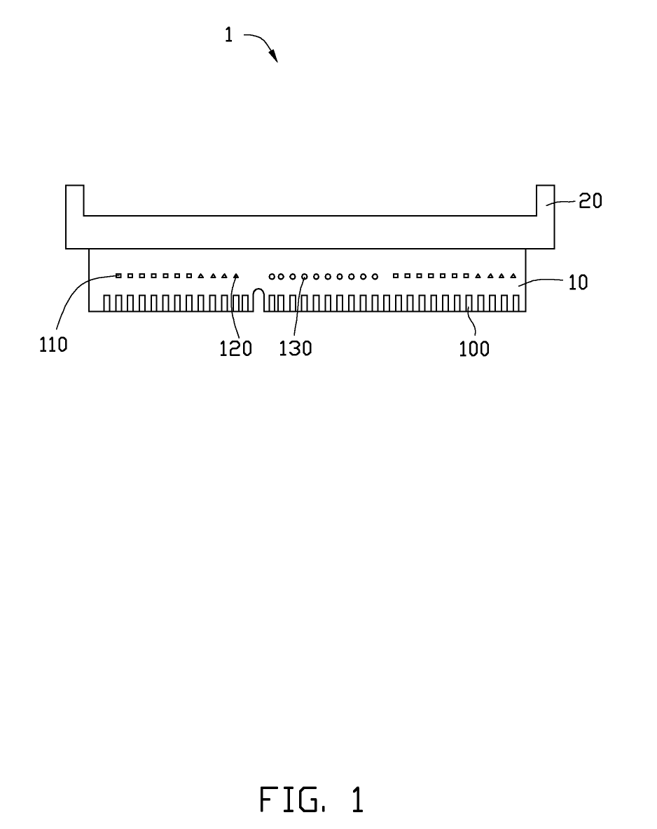

Referring to FIG. 1, an exemplary embodiment of a test apparatus 1 includes a circuit board 10 and a first expansion slot 20. A plurality of golden fingers are arranged on a first side of the circuit board 10. A second side of the circuit board 10 is connected to a bottom of the first expansion slot 20. The first expansion slot 20 is electrically connected to the golden fingers 100.

A plurality of first test pads 110, a plurality of second test pads 120, and a plurality of third test pads 130 are arranged on the circuit board 10 between the first and second sides. The test pads 110, 120, and 130 are electrically connected to the expansion slot 20 correspondingly.

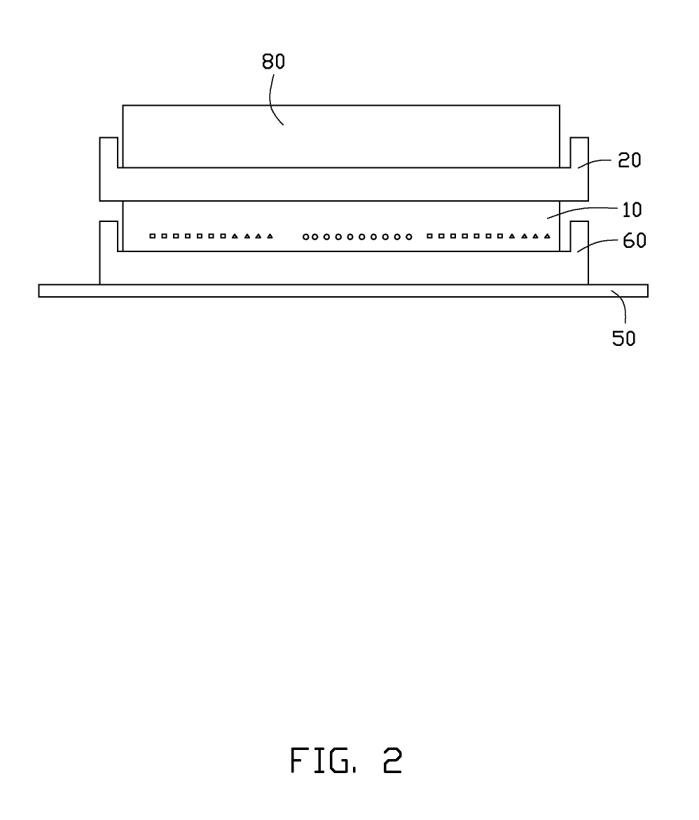

Referring to FIG. 2, in use, the first side of the circuit board 10 is plugged into a second expansion slot 60 on a motherboard 50, and a memory 80 is plugged into the first expansion slot 20. As a result, when the motherboard 50 operates, the memory 80 communicates with the motherboard 50 through the first expansion slot 20, the golden fingers 100, and the second expansion slot 60. Moreover, because the test pads 110, 120, and 130 are electrically connected to the first expansion slot 20, and the memory 80 is plugged into the first expansion slot 20, the test pads 110, 120, and 130 are electrically connected to the golden fingers of the memory 80 correspondingly. As a result, the test pads 110, 120, and 130 can be easily contacted by test probes for testing the memory 80.

In the embodiment, the first test pads 110, the second test pads 120, and the third test pads 130 have different colors, sizes, and/or shapes. For example, the first test pads 110 are rectangular, representing power signals and ground signals. The second test pads 120 are triangular, representing data signals. The third test pads 130 are circular, representing differential signals. As a result, testers can easily identify corresponding test pads when different signals need to be tested.

In the embodiment, the first expansion slot 20 has the same structure as the second expansion slot 60. The second expansion slot 60 is a memory slot.

The foregoing description of the exemplary embodiments of the disclosure has been presented only for the purposes of illustration and description and is not intended to be exhaustive or to limit the disclosure to the precise forms disclosed. Many modifications and variations are possible in light of the above everything. The embodiments were chosen and described in order to explain the principles of the disclosure and their practical application so as to enable others of ordinary skill in the art to utilize the disclosure and various embodiments and with various modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than the foregoing description and the exemplary embodiments described therein.

What is claimed is:

1. A test apparatus comprising:
a circuit board comprising a plurality of golden fingers arranged on a first side of the circuit board, and a plurality of first test pads and a plurality of second test pads arranged on the circuit board between the first side and a second side, the first and second test pads having different shapes, sizes, and/or colors; and
an expansion slot, wherein the second side of the circuit board is connected to a bottom of the expansion slot, the golden fingers of the circuit board are electrically connected to the expansion slot, and the first and second test pads are electrically connected to the expansion slot.

2. The test apparatus of claim 1, wherein the expansion slot is a memory slot.

3. The test apparatus of claim 1, wherein the circuit board further comprises a plurality of third test pads arranged on the circuit board between the first and second sides, shapes, sizes, and/or colors of the third test pads are different from the first and second test pads.
